(19) United States
(12) Patent Application Publication
(10) Pub. No.: US 2016/0155616 A1
(43) Pub. Date: Jun. 2, 2016

(54) SUBSTRATE PROCESSING APPARATUS

(71) Applicant: SAMSUNG ELECTRONICS CO., LTD., Suwon-si (KR)

(72) Inventors: Suho LEE, Gyeonggi-do (KR); Sung-Gyu PARK, Gyeonggi-do (KR); Jongrok PARK, Seoul (KR); Jinhyuk CHOI, Gyeonggi-do (KR); Moonhyeong HAN, Seoul (KR); Sangchul HAN, Gyeonggi-do (KR)

(21) Appl. No.: 14/815,346

(22) Filed: Jul. 31, 2015

(30) Foreign Application Priority Data
Dec. 2, 2014 (KR) 10-2014-0170590

(51) Int. Cl. H01J 37/32; C23C 16/46; C23C 16/455; C23C 16/458; C23C 16/511

(52) U.S. Cl. CPC H01J 37/32642; C23C 16/4584; C23C 16/511; C23C 16/4586; C23C 16/4558; C23C 16/46; H01J 37/3222; H01J 37/3266; H01J 37/32715; H01J 37/32522; H01J 37/32825; H01J 37/32633; H01J 2237/3321; H01J 2237/3341; H01J 2237/3387; H01J 2237/338

(57) ABSTRACT

A substrate processing apparatus includes a chamber, and a plasma generator disposed at an upper portion of the chamber. A susceptor is disposed in the chamber. The susceptor supports the substrate. A gas-distributing plate is configured to transfer plasma generated in the plasma generator to the susceptor. A rotating part is disposed under the chamber. The rotating part is configured to rotate the susceptor.

### CROSS-REFERENCE TO RELATED APPLICATION

This application claims priority under 35 U.S.C. §119 to Korean Patent Application No. 10-2014-0170590 filed on Dec. 2, 2014, the disclosure of which is incorporated by reference herein in its entirety.

### TECHNICAL FIELD

Exemplary embodiments of the present inventive concept relate to a processing apparatus, and more particularly to a substrate processing apparatus.

### DISCUSSION OF RELATED ART

Uniformity of a chemical vapor deposition (CVD) process or an etching process is a factor which may affect a yield of a substrate. As circuit patterns of semiconductor devices become fine-sized, the importance of substrate uniformity may increase. Accordingly, in a process of depositing a silicon layer in a fine pattern structure, multiple factors may be adjusted to increase substrate uniformity. For example, while a substrate is being processed, confinement by a gas plate of plasma in a chamber through which the plasma passes may be a factor in reducing substrate uniformity. A method of distributing a gas injected into the chamber may affect substrate uniformity.

### SUMMARY

Exemplary embodiments of the present inventive concept provide a substrate processing apparatus which uniformly processes a substrate.

Exemplary embodiments of the present inventive concept provide a substrate processing apparatus including a susceptor and a rotating part which rotates the susceptor.

Exemplary embodiments of the present inventive concept provide a gas-distributing plate having an asymmetric shape, and a substrate processing apparatus including the gas-distributing plate.

According to an exemplary embodiment of the present inventive concept, a substrate processing apparatus includes a chamber, and a plasma generator disposed at an upper portion of the chamber. A susceptor is disposed in the chamber. The susceptor supports the substrate. A gas-distributing plate is configured to transfer plasma generated in the plasma generator to the susceptor. A rotating part is disposed under the chamber. The rotating part is configured to rotate the susceptor.

In some exemplary embodiments of the present inventive concept, the plasma generator may include a microwave generator disposed outside the chamber. An antenna is disposed in the chamber. A plasma space is disposed in the chamber, and a gas inlet tube is disposed in the plasma space.

In some exemplary embodiments of the present inventive concept, the gas-distributing plate may include a plurality of gas-distributing openings through which the plasma passes, and a frame defining the gas-distributing openings.

In some exemplary embodiments of the present inventive concept, the plurality of the gas-distributing openings may include an outer annular opening and an inner circular opening

In some exemplary embodiments of the present inventive concept, the frame may include an outer ring-type frame surrounding the outer annular opening and defining an outline of the gas-distributing plate, and an inner ring-type frame separating and defining the outer annular opening and the inner circular opening.

In some exemplary embodiments of the present inventive concept, a diameter of the inner circular opening may be substantially the same as or greater than a diameter of the substrate.

In some exemplary embodiments of the present inventive concept, the frame may further include an outer radial frame connecting the outer ring-type frame to the inner ring-type frame and dividing the outer annular opening into a plurality of outer arcuate openings, and a plurality of inner linear frames dividing the inner circular opening into a plurality of inner polygonal openings.

In some exemplary embodiments of the present inventive concept, the plurality of the inner linear frames may include at least one X-directional inner linear frame crossing the inner circular opening in an X-direction, and at least one Y-directional inner linear frame crossing the inner circular opening in a Y-direction. to the at least one Y-directional inner linear frame may be perpendicular to the X-directional inner linear frame.

In some exemplary embodiments of the present inventive concept, a geometric center of the inner ring-type frame does not match a geometric center of the plurality of the inner linear frames. Geometric shapes of the plurality of the inner linear frames may be asymmetric in the inner circular opening.

In some exemplary embodiments of the present inventive concept, the frame may include a plurality of inner concentric ring-type frames separating and defining the inner circular opening into a plurality of inner concentric annular openings. A plurality of inner radial frames may separate and define the plurality of the inner concentric annular openings into a plurality of inner arcuate openings. The plurality of the inner concentric ring-type frames and the plurality of the inner radial frames may form a cobweb shape.

In some exemplary embodiments of the present inventive concept, the plurality of the inner radial frames is not linearly continuous from a geometric center of the cobweb shape to the inner ring-type frame. Each of the plurality of the inner concentric ring-type frames may have a zigzag shape including two or more diameters along a circumference of the plurality of the inner concentric ring-type frames.

In some exemplary embodiments of the present inventive concept, the inner ring-type frame may include a plurality of gas inlet holes.

In some exemplary embodiments of the present inventive concept, the rotating part may include a hollow shaft through which a lower portion of the susceptor passes. A housing may surround an outer surface of the hollow shaft, and a rotation driver may be connected to a lower portion of the hollow shaft.

In some exemplary embodiments of the present inventive concept, the housing may include a magnetic member disposed in the housing. A magnetic fluid may be disposed on an inner circumferential surface of the housing, and a cooling part may be disposed on an outer circumferential surface of the housing.

In some exemplary embodiments of the present inventive concept, the substrate processing apparatus may include a baffle disposed under the susceptor. The baffle may include a plurality of radial slits. A vacuum pump may be disposed under the baffle. The vacuum pump may be configured to evacuate the inside of the chamber.

According to an exemplary embodiment of the present inventive concept, a substrate processing apparatus includes a vacuum chamber, and a plasma generator disposed at an upper portion of the vacuum chamber. The plasma generator includes a gas inlet tube. A susceptor is disposed in the vacuum chamber. The susceptor supports the substrate. A gas-distributing plate is configured to transfer plasma generated in the plasma generator to the susceptor. A baffle is disposed under the susceptor. The baffle includes a plurality of slits. A pocket chamber is disposed outside the vacuum chamber. The pocket member includes a rotating part configured to rotate the susceptor. A vacuum pump is disposed at a lower portion of the vacuum chamber. The vacuum pump is configured to evacuate the vacuum chamber.

According to an exemplary embodiment of the present inventive concept, a substrate processing apparatus includes a vacuum chamber, a plasma generator disposed at an upper portion of the vacuum chamber, a susceptor disposed at an intermediate portion of the vacuum chamber and supporting the substrate, a gas-distributing plate disposed between the plasma generator and the susceptor, and a pocket chamber disposed outside and under the vacuum chamber. The pocket chamber includes a rotating part configured to rotate the susceptor.

In some exemplary embodiments of the present inventive concept, the gas-distributing plate may include gas-distributing openings including an outer annular opening and an inner circular opening through which the plasma passes, and an outer ring-type frame defining an outline of the gas-distributing openings and an inner ring-type frame configured to separate and define the outer annular opening and the inner circular opening. The outer ring-type frame and the inner ring-type frame may be concentric circles.

In some exemplary embodiments of the present inventive concept, the gas-distributing plate may include an X-directional inner linear frame and a Y-directional inner linear frame dividing the inner circular opening into a plurality of inner polygonal openings, and a geometric center of the inner ring-type frame need not match a geometric center of the X-directional and Y-directional inner linear frames.

In some exemplary embodiments of the present inventive concept, the gas-distributing plate may include inner radial frames dividing the inner circular opening into a plurality of inner concentric annular openings, and inner concentric ring-type frames dividing the plurality of the inner concentric annular openings into a plurality of inner arcuate openings. A geometric center of the inner ring-type frame need not match a geometric center of the inner concentric ring-type frames.

In some exemplary embodiments of the present inventive concept, the rotating part may include a hollow shaft through which a lower portion of the susceptor passes, a housing surrounding an outer surface of the hollow shaft, and a rotation driver connected to a lower portion of the hollow shaft.

In some exemplary embodiments of the present inventive concept, the housing may include a magnetic member disposed in the housing, a magnetic fluid disposed on an inner circumferential surface of the housing, and a cooling part disposed on an outer circumferential surface thereof.

According to an exemplary embodiment of the present inventive concept, a substrate processing apparatus includes a vacuum chamber, a plasma generator disposed at an upper portion of the vacuum chamber, a susceptor disposed at an intermediate portion of the vacuum chamber and supporting the substrate, a gas-distributing plate disposed between the plasma generator and the susceptor, and a pocket chamber disposed outside and under the vacuum chamber. The pocket chamber includes a rotating part configured to rotate the susceptor.

In some exemplary embodiments of the present inventive concept, the gas-distributing plate may include gas-distributing openings including an outer annular opening and an inner circular opening through which the plasma passes, and an outer ring-type frame defining an outline of the gas-distributing openings and an inner ring-type frame configured to separate and define the outer annular opening and the inner circular opening. The outer ring-type frame and the inner ring-type frame may be concentric circles.

In some exemplary embodiments of the present inventive concept, the gas-distributing plate may include an X-directional inner linear frame and a Y-directional inner linear frame dividing the inner circular opening into a plurality of inner polygonal openings. A geometric center of the inner ring-type frame may do not match a geometric center of the X-directional and Y-directional inner linear frames.

In some exemplary embodiments of the present inventive concept, the gas-distributing plate may include inner radial frames dividing the inner circular opening into a plurality of inner concentric annular openings, and inner concentric ring-type frames dividing the plurality of inner concentric annular openings into a plurality of inner arcuate openings,

In some exemplary embodiments of the present inventive concept, a geometric center of the inner ring-type frame may do not match a geometric center of the inner concentric ring-type frames.

In some exemplary embodiments of the present inventive concept, the rotating part may include a hollow shaft through which a lower portion of the susceptor passes, a housing surrounding an outer surface of the hollow shaft, and a rotation driver connected to a lower portion of the hollow shaft.

In some exemplary embodiments of the present inventive concept, the housing may include a magnetic member disposed thereinside, a magnetic fluid disposed on an inner circumferential surface thereof, and a cooling part disposed on an outer circumferential surface thereof.

Exemplary embodiments of the present inventive concept are described in more detail in the detailed description of the embodiments and drawings.

### BRIEF DESCRIPTION OF THE DRAWINGS

The above and other features of the inventive concept will become more apparent by describing in detail exemplary embodiments thereof, with reference to the accompanying drawings in which:

FIG. 1 is a diagram schematically illustrating a substrate processing apparatus in accordance with an exemplary embodiment of the present inventive concept;

FIGS. 2A to 2D are diagrams schematically illustrating gas-distributing plates in accordance with exemplary embodiments of the present inventive concept;

FIG. 3 is a lateral cross-sectional view of a substrate processing apparatus in accordance with an exemplary embodiment of the present inventive concept, which is taken along line I-I′ of FIG. 1.;

FIG. 4 is a diagram schematically illustrating a cooling part of a substrate processing apparatus in accordance with an exemplary embodiment of the present inventive concept;

FIGS. 5A to 5C are deposition distribution diagrams obtained after processing a substrate using a substrate processing apparatus in accordance with an exemplary embodiment of the present inventive concept; and

FIG. 6 is a flowchart illustrating a method of processing a substrate using a substrate processing apparatus in accordance with an exemplary embodiment of the present inventive concept.

### DETAILED DESCRIPTION OF THE EMBODIMENTS

Various exemplary embodiments of the present inventive concept will be described in more detail below with reference to the accompanying drawings in which some exemplary embodiments of the present inventive concept are shown. Exemplary embodiments of the present inventive concept may, however, be embodied in different forms and should not be construed as limited to the embodiments set forth herein.

The terminology used herein to describe exemplary embodiments of the present inventive concept is not intended to limit the scope of the inventive concept.

Exemplary embodiments of the present inventive concept may be described herein with reference to cross-sectional and/or planar illustrations that are schematic illustrations of idealized embodiments and intermediate structures. In the drawings, the sizes and relative sizes of layers and regions may be exaggerated for clarity. As such, variations from the shapes of the illustrations as a result, for example, of manufacturing techniques and/or tolerances, may occur. Thus, exemplary embodiments of the present inventive concept should not be construed as limited to the particular shapes of regions illustrated herein but are to include deviations in shapes that result, for example, from manufacturing.

Like reference numerals may refer to like elements throughout the specification and drawings. Accordingly, the same numerals and similar numerals may be described with reference to different drawings, even if not specifically described in the corresponding drawings. When a numeral is not marked in a drawing, the numeral may be described with reference to other drawings.

Technical aspects of the present inventive concept are not limited to the technical aspects described herein; other aspects of the present inventive concept may become apparent to those of ordinary skill in the art based on the descriptions included herein.

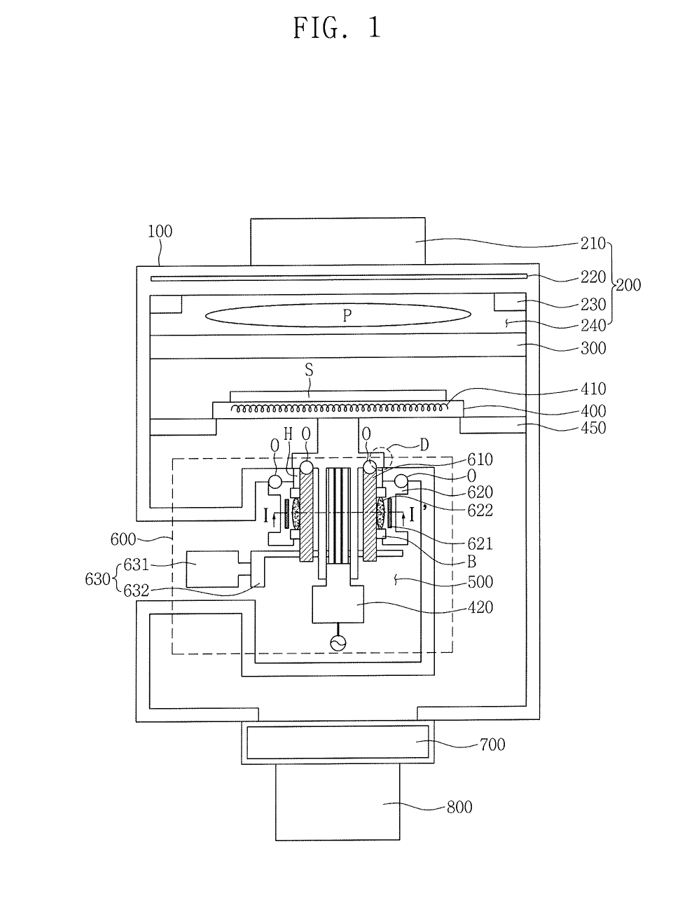

FIG. 1 is a diagram schematically illustrating a substrate processing apparatus in accordance with an exemplary embodiment of the present inventive concept.

Referring to FIG. 1, a substrate processing apparatus in accordance with an exemplary embodiment of the present inventive concept may include a vacuum chamber 100 and a rotating part 600.

The vacuum chamber 100 may perform various processes such as a chemical vapor deposition (CVD) process, a reactive ion etching (RIE) process, an oxidation process, and a nitration process, in a vacuum state. The vacuum chamber 100 may include a plasma generator 200, a gas-distributing plate 300, a susceptor 400, a baffle 450, and a vacuum pump 800 disposed at a lower portion of the vacuum chamber 100.

The plasma generator 200 may include a microwave generator 210, an antenna 220, a gas inlet tube 230, and a plasma space 240. The microwave generator 210 may be disposed at an upper portion of the vacuum chamber 100. The microwave generator may generate microwaves of different frequencies depending on the process performed in the vacuum chamber 100. The frequencies may be, for example, 1.98 MHz, 2.45 MHz, 8.35 MHz, or 13.56 MHz. The antenna 220 may be buried in an upper plate of the vacuum chamber 100. The antenna 220 may receive the generated microwaves from the microwave generator 210 and may transmit the microwaves to the plasma space 240.

The gas inlet tube 230 may be disposed in the plasma space 240. The gas inlet tube 230 may have a ring shape. The gas inlet tube 230 may be disposed on an upper sidewall of the vacuum chamber 100. The gas inlet tube 230 may supply a first process gas to the plasma space 240. The first process gas may be, for example, Ar, N₂, O₂, N₂O, O₃, He, SiH₄, GeH₄, H₂, B₂H₆, PH₃, CH₄, or NO.

The plasma space 240 may be disposed between the antenna 220 and the gas-distributing plate 300 in the vacuum chamber 100. In the plasma space 240, the first process gas may be excited to plasma P by the microwaves transmitted from the antenna 220.

The gas-distributing plate 300 may be disposed between the plasma space 240 and the susceptor 400. The gas-distributing plate 300 may be disposed 40 mm or more, based on height, from the susceptor 400. The gas-distributing plate 300 may include a metal, such as Al, an Al alloy, steel, stainless steel, Ni, or a Ni alloy (e.g., Inconel®, or Hastelloy®), or a ceramic dielectric, such as quartz, SiC, SiN, Al₂O₃, AlN, or Y₂O₃. In accordance with an exemplary embodiment of the present inventive concept, the gas-distributing plate 300 may include Al and may have relatively high corrosion resistance, reactivity, conductivity, and processability. The gas-distributing plate 300 may transfer the plasma P generated in the plasma space 240 to be distributed in the susceptor 400. Exemplary embodiments of the gas-distributing plate 300 will be described below in more detail.

The susceptor 400 may be disposed under the gas-distributing plate 300 and may have a T-shaped longitudinal cross-section. The susceptor 400 may stably support a substrate S while a process is performed on the substrate S. The susceptor 400 may include a heater 410 configured to heat the substrate S. The heater 410 may be disposed at an upper portion of inside the susceptor 400 at an upper portion of the susceptor 400. The upper portion of the susceptor 400 may support the substrate S. The susceptor 400 may maintain a temperature of the substrate S using the heater 410 while a process is performed on the substrate S. A lower portion of the susceptor 400 may pass through a through-hole H of the vacuum chamber 100 and may be connected to the rotating part 600 located outside the vacuum chamber 100. Accordingly, the susceptor 400 may be rotated by the rotating part 600 while a process is performed on the substrate S. Accordingly, the susceptor 400 may allow a non-uniform film disposed on substrate S to become smooth or more uniform. The susceptor 400 may electro-statically adsorb and support the substrate S. A slip ring 420 may be coupled to a lower portion of the susceptor 400. The slip ring 420 may connect exposed wires of the heater 410 in the susceptor 400 to an external power source. The slip ring 420 may reduce or prevent an occurrence of kinking in the wires when the susceptor 400 rotates. The slip ring 420 may be integrated with the susceptor 400 and may facilitate attachment and detachment when the susceptor 400 is installed in the vacuum chamber 100.

The baffle 450 may be disposed on an outer surface of the susceptor 400. The baffle 450 may uniformly exhaust a process gas to a lower portion of the vacuum chamber 100. Accordingly, the baffle 450 may maintain a constant flow of the process gas around the substrate S disposed on the susceptor 400. An outer diameter of the baffle 450 may have a size that is similar to a diameter of an inner circumferential surface of the vacuum chamber 100. A plurality of slits may be radially disposed between the inner diameter and the outer diameter of an upper portion of the baffle 450. The process gas may be uniformly exhausted by the plurality of the slits to the lower portion of the vacuum chamber 100.

The vacuum pump 800 may be disposed under the baffle 450 and may evacuate the inside of the vacuum chamber 100. The vacuum pump 800 may exhaust a foreign material or a residual gas from the vacuum chamber 100. The vacuum pump 800 may adjust a pressure of the inside of the vacuum chamber 100 to match process conditions by repeatedly opening and closing a valve 700. In some exemplary embodiments of the present inventive concept, in a gap-fill process in which a gap between metals or a trench is filled, since a deposition rate may be relatively faster at a sidewall of an upper corner between the metals or the trench in an ultrafine process, an insulating layer (SiO₂ or SiOF) may be re-deposited. Accordingly, an entrance of the trench or an entrance of the gap between the metals may be clogged and a void may occur. In this case, a high vacuum state may be used to slow down the mobility of an active species of the plasma. The vacuum pump 800 may include a turbo molecular pump (TMP) rotating at a relatively high speed. For example, the TMP may rotate at about 3000 rpm or more and may exhaust the foreign material or the remaining gas in the vacuum chamber 100 so that the vacuum chamber 100 maintains the high vacuum state. For example, the vacuum chamber 100 may maintain a vacuum state of about 1 Torr or less.

A pocket-type space 500 in which the rotating part 600 is disposed may be disposed at one side of the vacuum chamber 100. The pocket-type space 500 of the vacuum chamber 100 may be in an atmospheric pressure state.

The rotating part 600 may be disposed under the susceptor 400 in the pocket-type space 500 of the vacuum chamber 100. The rotating part 600 may be connected to the susceptor 400 and may rotate the susceptor 400. The rotating part 600 may include a hollow shaft 610, a housing 620, and a rotation driver 630.

The hollow shaft 610 may be disposed under the susceptor 400. The hollow shaft 610 may have a through tube passing through the lower portion of the susceptor 400. The through tube of the hollow shaft 610 may have a greater diameter than the slip ring 420. The hollow shaft 610 may be disposed between the susceptor 400 and the through-hole H of the vacuum chamber 100. The susceptor 400 may pass through the hollow shaft 610. An upper end of the hollow shaft 610 may be sealed using an O-ring O disposed at a portion of the hollow shaft 610 in contact with a protrusion D formed in the middle of the susceptor 400. The hollow shaft 610 may be coupled to the susceptor 400. The hollow shaft 610 may include slits on an outer circumferential surface thereof. The slits on the outer circumferential surface of the hollow shaft 610 may allow a magnetic fluid 622 which will be described below in more detail, to be more stably positioned.

The housing 620 may have a structure surrounding an outer surface of the hollow shaft 610, and may be disposed between the hollow shaft 610 and the through-hole H of the vacuum chamber 100. An interface between the housing 620 and the vacuum chamber 100 may be sealed with an O-ring O, and an interface between the housing 620 and the hollow shaft 610 may be sealed by a magnetic fluid. The housing 620 may include a bearing B which supports the hollow shaft 610 to be freely rotatable in the housing 620. The magnetic fluid 622 may seal a space between the hollow shaft 610 and the housing 620 using a magnetic force. The magnetic fluid 622 may maintain the vacuum chamber 100 in a vacuum state when the hollow shaft 610 rotates, and may prevent an external foreign material from entering the vacuum chamber 100.

The rotation driver 630 may be disposed under the hollow shaft 610 and may be connected to the hollow shaft 610. The rotation driver 630 may include a motor 631 which provides a rotating force, and a bevel gear 632 which transfers the rotating force. An end of the bevel gear 632 may be directly connected to the hollow shaft 610, and the other end of the bevel gear 632 may be connected to the motor 631. Accordingly, the rotation driver 630 may rotate the hollow shaft 610 by the rotating force. For example, the susceptor 400 coupled to the hollow shaft 610 may be rotated by the rotation driver 630. The rotation driver 630 may change a rotational speed depending on a process performed on the substrate S. For example, the rotation driver 630 may operate at a rotational speed of about 60 rpm or less. In some exemplary embodiments of the present inventive concept, the rotation driver 630 may be operated at about 10 rpm or less. When a velocity of acceleration/deceleration of the rotation driver 630 is more than a predetermined velocity, the processing of the substrate S may become difficult due to slippage of the substrate S. When the gap-fill process is performed, a deposition/etching rate in a center portion of the substrate S may differ from a deposition/etching rate in an outer portion of the substrate S depending on a rotational speed of the rotation driver 630. Accordingly, the velocity of acceleration/deceleration of the rotation driver 630 may be about 10 rpm or less when the rotational speed of the rotation driver 630 is changed.

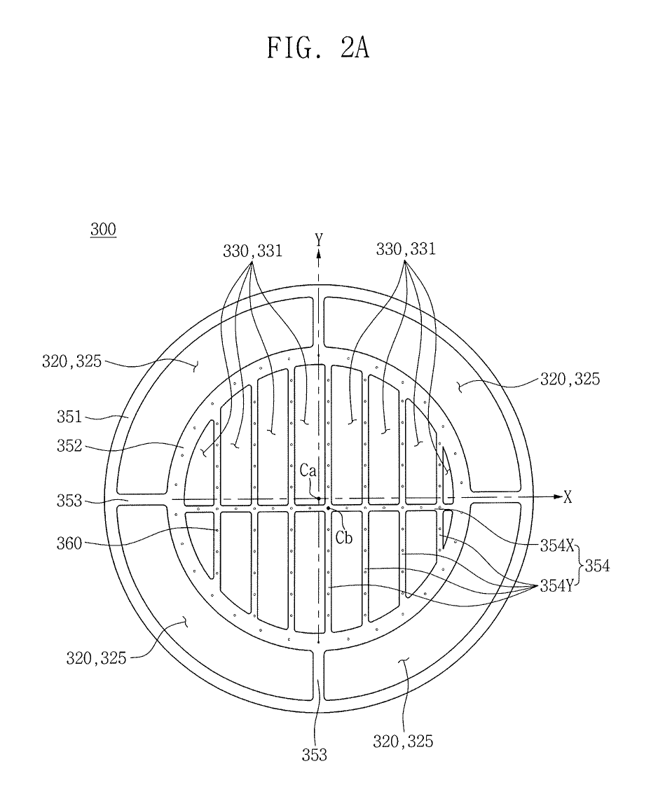

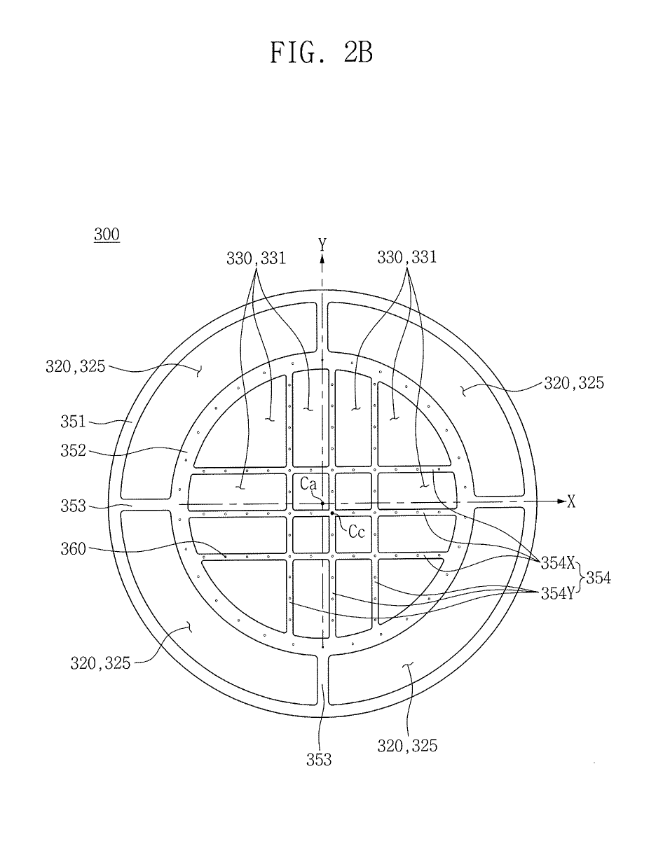

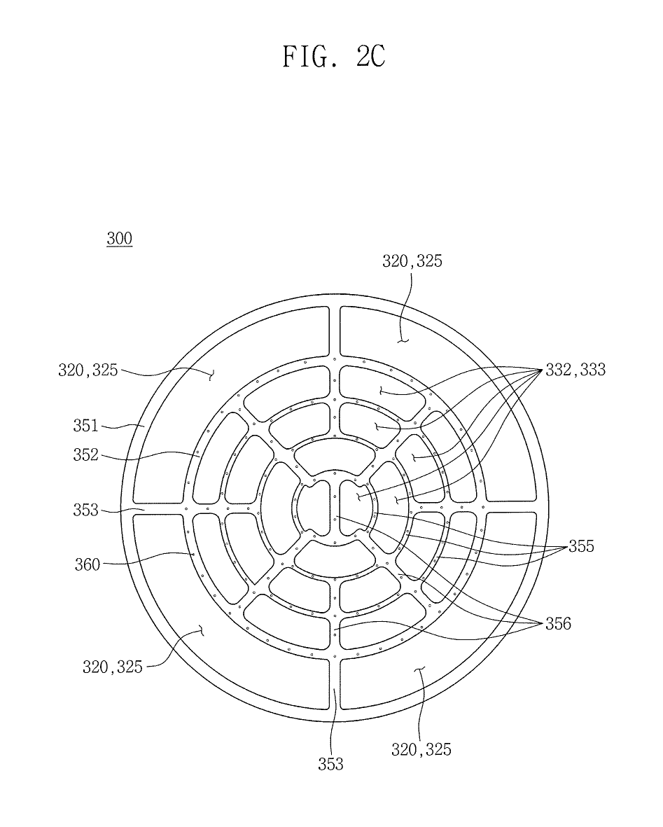

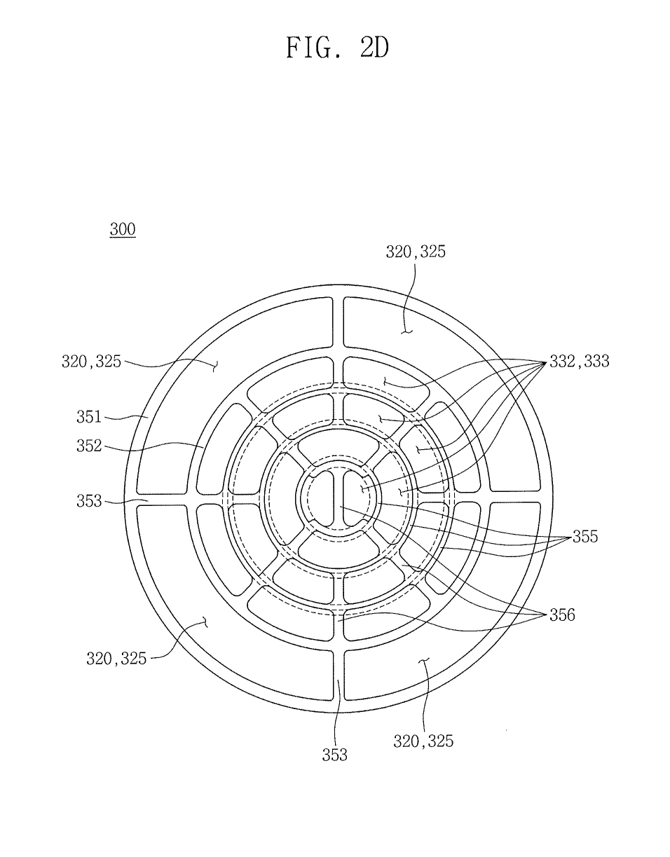

FIGS. 2A to 2D are diagrams schematically illustrating gas-distributing plates in accordance with exemplary embodiments of the present inventive concept.

Referring to FIGS. 2A and 2B, the gas-distributing plate 300 in accordance with an exemplary embodiment of the present inventive concept may include gas-distributing openings 320 and 330 through which plasma may pass, and frames 351, 352, 353, and 354 which define the gas-distributing openings 320 and 330.

The gas-distributing openings 320 and 330 may include an outer annular opening 320 and an inner circular opening 330. The frames 351, 352, 353, and 354 may include an outer ring-type frame 351 configured to define an outline of the gas-distributing plate 300 by surrounding the outer annular opening 320, and an inner ring-type frame 352 configured to separate and define the outer annular opening 320 and the inner circular opening 330. The outer ring-type frame 351 and the inner ring-type frame 352 may be concentric circles. The inner ring-type frame 352 may have a greater diameter than a diameter of the substrate S, and thus the inner circular opening 330 may supply sufficient plasma to the substrate S disposed on the susceptor 400. For example, when the diameter of the substrate S is about 300 mm, the diameter of the inner circular opening 330 may be about 10% greater than that of the substrate S. For example, the inner ring-type frame 352 may have a diameter of about 330 mm or more.

The frames 351, 352, 353, and 354 may include outer radial frames 353 which connect the outer ring-type frame 351 to the inner ring-type frame 352. The outer radial frames 353 may divide the outer annular opening 320 into a plurality of outer arcuate openings 325.

The frames 351, 352, 353, and 354 may include inner linear frames 354 which divide the inner circular opening 330 into a plurality of inner polygonal openings 331. The inner linear frames 354 may include one or more X-directional inner linear frames 354X extending in an X-direction, and Y-directional inner linear frames 354Y extending in a Y-direction perpendicular to the X direction. For example, the X-directional inner linear frames 354X and the Y-directional inner linear frames 354Y may be perpendicular to each other or may form a grid structure. The inner polygonal openings 331 may have various geometric shapes, such as a rectangular shape or a fan shape.

A geometric center Ca of the inner circular opening 330 or the inner ring-type frame 352 need not match geometric centers Cb and Cc of the inner linear frames 354. For example, a geometric shape of the inner linear frames 354 may be asymmetric with respect to an X-axis (X) and/or Y-axis (Y) which passes through the geometric center Ca of the inner ring-type frame 352 and the inner linear frames 354 in the X-direction and/or the Y-direction in the inner circular opening 330. Referring to FIGS. 2A and 2B, for example, the geometric centers Cb and Cc of the inner linear frames 354 may be disposed at a fourth quadrant defined by the X-axis (X) and the Y-axis (Y).

The frames 351, 352, 353, and 354 may include a plurality of gas inlet holes 360. For example, the inner ring-type frame 352 and the inner linear frames 354 may include the plurality of the gas inlet holes 360. The gas inlet holes 360 may be disposed facing the susceptor 400. The gas inlet holes 360 may supply a second process gas to the susceptor 400. The second process gas may include, for example, SiH₄, GeH₄, H₂, B₂H₆, PH₃, CH₄, Ar, N₂, O₂, N₂O, O₃, He, or NO.

The gas-distributing plate 300 may distribute the plasma P and the second process gas to an outer portion and a center portion of the substrate S. That is, the gas-distributing plate 300 may transfer the plasma P through the outer arcuate openings 325 and the inner polygonal openings 331. The gas-distributing plate 300 may distribute the second process gas to the outer portion of the substrate S through the plurality of the gas inlet holes 360 formed in the inner ring-type frame 352, and to the center portion of the substrate S through the plurality of the gas inlet holes 360 formed in the inner linear frames 354. Accordingly, the gas-distributing plate 300 may control a pattern of a gas flow. The gas-distributing plate 300 may uniformly distribute the plasma P without overlapping of frames corresponding to the substrate S while the susceptor 400 performs rotational motion.

Referring to FIGS. 2C and 2D, the gas-distributing plate 300 in accordance with an exemplary embodiment of the present inventive concept may include gas-distributing openings 320 and 330 through which plasma may pass, and frames 351, 352, 353, 355, and 356 defining the gas-distributing openings 320 and 330. The gas-distributing openings 320 and 330 may include the outer annular opening 320 and the inner circular opening 330. The frames 351, 352, 353, 355, and 356 may include an outer ring-type frame 351 defining an outline of the gas-distributing plate 300, and an inner ring-type frame 352 separating and defining the outer annular opening 320 and the inner circular opening 330. The frames 351, 352, 353, 355, and 356 may include outer radial frames 353 connecting the outer ring-type frame 351 and the inner ring-type frame 352. The outer radial frames 353 may divide the outer annular opening 320 into a plurality of outer arcuate openings 325.

The frames 351, 352, 353, 355, and 356 may include a plurality of inner concentric ring-type frames 355 which divide the inner circular opening 330 into a plurality of inner concentric annular openings 332, and inner radial frames 356 which divide the plurality of the inner concentric annular openings 332 into a plurality of inner arcuate openings 333.

The inner concentric ring-type frames 355 and the inner radial frames 356 may form a cobweb shape.

The frames 351, 352, 353, 355, and 356 may include a plurality of the gas inlet holes 360. For example, the inner ring-type frames 352, the inner concentric ring-type frames 355, and the inner radial frames 356 may include the plurality of the gas inlet holes 360. The gas inlet holes 360 may be disposed facing the susceptor 400. The plurality of the gas inlet holes 360 may supply the second process gas to the susceptor 400. The second process gas may include, for example, SiH₄, GeH₄, H₂, B₂H₆, PH₃, CH₄, Ar, N₂, O₂, N₂O, O₃, He, or NO.

Referring to FIG. 2D, each of the inner concentric ring-type frames 355 need not have a single continuous circular or ring shape. One inner concentric ring-type frame 355 may selectively have a circular shape having at least two diameters (or radii). For example, the inner concentric ring-type frame 355 may have a zigzag shape along a circumference thereof. Various concentric circles according to an exemplary embodiment of the present invention are illustrated using dashed lines.

The inner radial frames 356 need not be linearly continuous from the geometric center of the cobweb shape to the inner ring-type frame 352.

Accordingly, the plurality of the inner arcuate openings 333 including a single inner concentric annular opening 332 may have various sizes.

Accordingly, the gas-distributing plate 300 may distribute the plasma P and the second process gas to an outer portion and a center portion of the substrate S. The gas-distributing plate 300 may transfer the plasma P through the outer arcuate openings 325 and the inner polygonal openings 331. The gas-distributing plate 300 may distribute the second process gas to the outer portion of the substrate S through the plurality of the gas inlet holes 360 formed in the inner ring-type frame 352, and to the center portion of the substrate S through the plurality of the gas inlet holes 360 formed in the inner linear frames 354. Accordingly, the gas-distributing plate 300 may control a pattern of a gas flow. The gas-distributing plate 300 may uniformly distribute the plasma P without overlapping of frames corresponding to the substrate S while the susceptor 400 performs rotational motion.

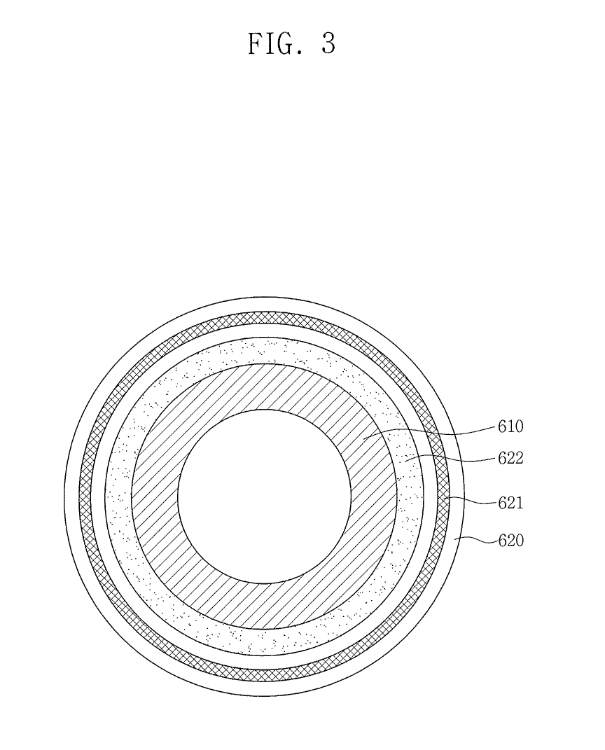

FIG. 3 is a lateral cross-sectional view of a substrate processing apparatus in accordance with an exemplary embodiment of the present inventive concept, which is taken along line I-I′ of FIG. 1. The susceptor 400 of FIG. 1 is omitted in FIG. 3 for clarity of description of the rotating part 600.

Referring to FIGS. 1 and 3, the hollow shaft 610, the magnetic fluid 622, and the housing 620 may be sequentially disposed in the rotating part 600. The housing 620 may include a magnetic member 621. The magnetic member 621 may include a magnetic material generating a cylindrical magnetic force. The magnetic material may be a permanent magnet. The magnetic member 621 may be disposed on an outer circumferential surface of the housing 620 or inside the housing 620. The magnetic fluid 622 may be disposed between the housing 620 and the magnetic member 621. A space between the housing 620 and the hollow shaft 610 may be sealed by a magnetic field of the magnetic member 621.

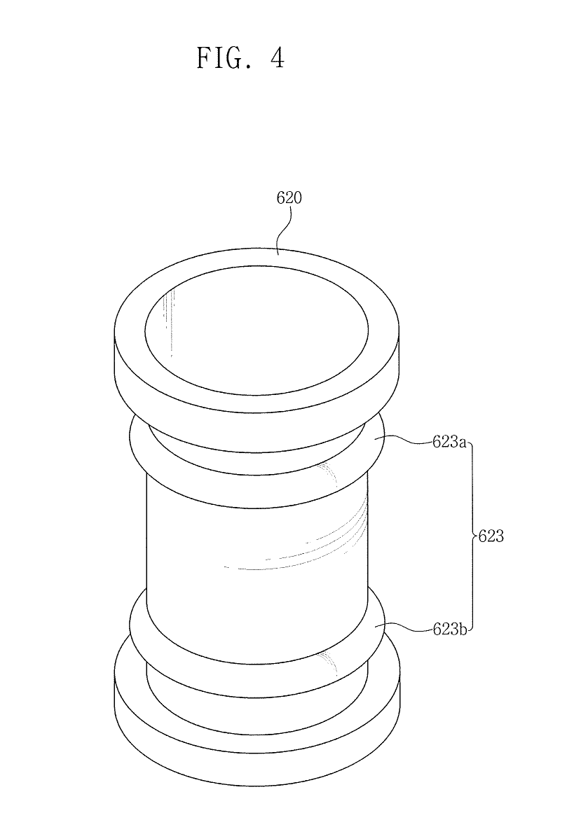

FIG. 4 is a diagram schematically illustrating a cooling part of a substrate processing apparatus in accordance with an exemplary embodiment of the present inventive concept.

Referring to FIGS. 1 and 4, the housing 620 may include a cooling part 623 disposed on the outer circumferential surface thereof. The cooling part 623 may cool the heat generated by rotation of the susceptor 400. The cooling part 623 may include an upper cooling part 623a and a lower cooling part 623b respectively disposed on an upper portion and a lower portion of an outer surface of the housing 620 in a ring shape. The cooling part 623 including an upper cooling part 623a and a lower cooling part 623b respectively disposed on an upper portion and a lower portion of an outer surface of the housing 620 in a ring shape may increase efficiency of a spatial arrangement of the cooling part 623. The upper cooling part 623a and the lower cooling part 623b may be disposed without occupying much space of the housing 620. One of the upper cooling part 623a or the lower cooling part 623b may be omitted. The cooling part 623 may be disposed on the entire outer circumferential surface of the housing 620. The cooling part 623 may include ammonia, freon, methyl chloride, helium, liquid hydrogen, or distilled water, as a refrigerant to lower a temperature.

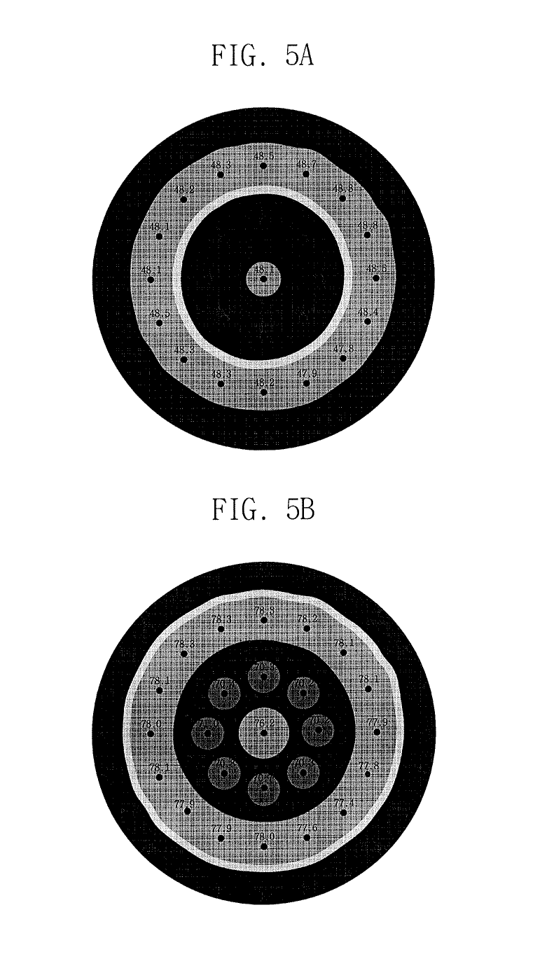

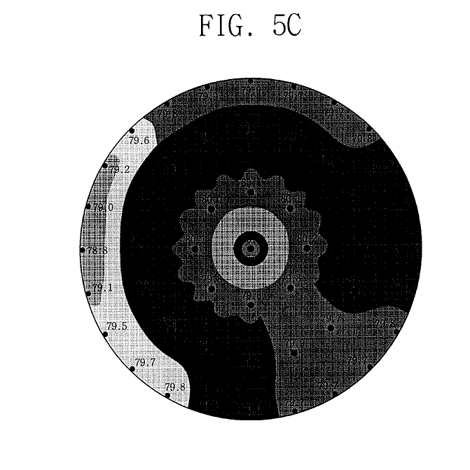

FIGS. 5A to 5C are deposition distribution diagrams obtained after processing a substrate using a substrate processing apparatus in accordance with an exemplary embodiment of the present inventive concept. Points and numbers in FIGS. 5A to 5C may refer to respective thicknesses measured at the points.

Referring to FIG. 5A, a mean value of a thickness of a material layer deposited on the substrate S using a normal substrate processing apparatus may be about 44.5 nm, a thickness variation from the mean value of the deposited material layer may be about 19.2 nm (21.6%), and a 3-sigma value for the thickness of the deposited material layer may be about 20.4 nm (45.8%).

Referring to FIG. 5B, the mean value of the thickness of the material layer deposited on the substrate S using another normal substrate processing apparatus may be about 80.3 nm, the thickness variation from the mean value of the deposited material layer may be about 15.6 nm (9.7%), and the 3-sigma value for the thickness of the deposited material layer may be about 16.6 nm (20.7%).

Referring to FIG. 5C, the mean value of the thickness of the material layer deposited on the substrate S using a substrate processing apparatus in accordance with an exemplary embodiment of the present inventive concept may be about 79.8 nm, the thickness variation from the mean value of the deposited material layer may be about 4.6 nm (2.9%), and the 3-sigma value for the thickness of the deposited material layer may be about 2.0 nm (2.5%).

The material layer deposited using the substrate processing apparatus in accordance with exemplary embodiments of the present inventive concept may be more uniform than the material layer deposited using the substrate processing apparatus in accordance with the normal method.

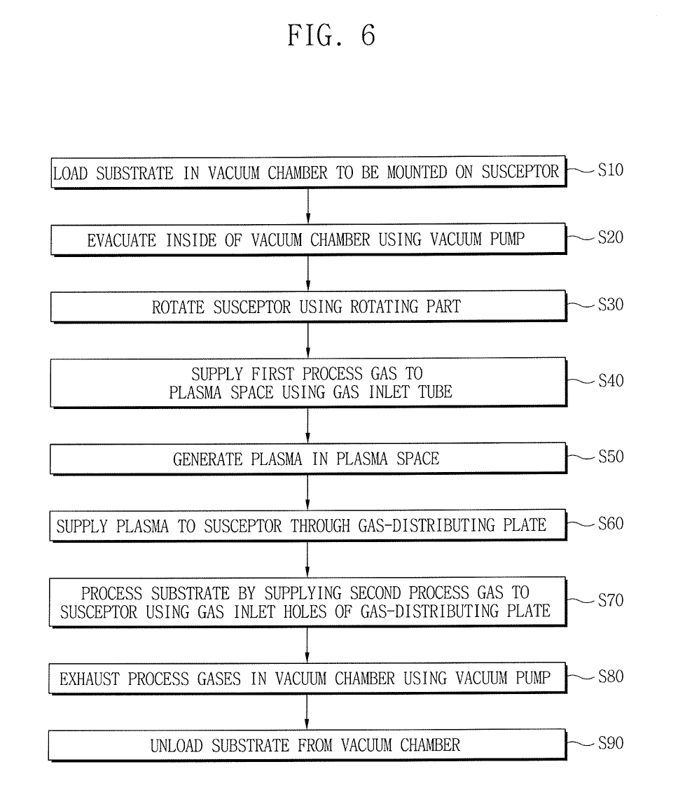

FIG. 6 is a flowchart illustrating a method of processing a substrate using a substrate processing apparatus in accordance with an exemplary embodiment of the present inventive concept.

Referring to FIGS. 1 and 6, the method of processing the substrate S using the substrate processing apparatus in accordance with an exemplary embodiment of the present inventive concept may include loading the substrate S in the vacuum chamber 100 and mounting the substrate S on the susceptor 400 (S10). The inside of the vacuum chamber 100 may be evacuated using the vacuum pump 800 (S20). The susceptor 400 may be rotated using the rotating part 600 (S30). The first process gas may be injected into the plasma space 240 using the gas inlet tube 230 (S40). Plasma may be generated in the plasma space 240 (S50). The plasma may be supplied to the susceptor 400 through the gas-distributing plate 300 (S60). The substrate S may be processed by supplying the second process gas to the susceptor 400 using the gas inlet holes 360 of the gas-distributing plate 300 (S70). The process gases in the vacuum chamber 100 may be exhausted using the vacuum pump 800 (S80). The substrate S may be unloaded to the outside of the vacuum chamber 100 (S90).

According to exemplary embodiments of the present inventive concept, the substrate S may be uniformly processed by an ultra fine process. Accordingly, a yield of the substrate S may be increased.

According to exemplary embodiments of the present inventive concept, the substrate S may be rotated and a uniformity of the substrate S may be increased due to the gases and plasma P diffused through the gas-distributing plate 300.

While the inventive concept has been particularly shown and described with reference to exemplary embodiments thereof, it will be understood by those of ordinary skill in the art that various changes in form and detail may be made therein without departing from the spirit and scope of the inventive concept.

1. A substrate processing apparatus, comprising:
a chamber;
a plasma generator disposed at an upper portion of the chamber;
a susceptor disposed in the chamber, wherein the susceptor supports the substrate;
a gas-distributing plate configured to transfer plasma generated in the plasma generator to the susceptor; and
a rotating part disposed under the chamber, wherein the rotating part is configured to rotate the susceptor.

2. The substrate processing apparatus of claim 1, wherein the plasma generator comprises:
a microwave generator disposed outside the chamber;
an antenna disposed in the chamber;
a plasma space disposed in the chamber; and
a gas inlet tube disposed in the plasma space.

3. The substrate processing apparatus of claim 1, wherein the gas-distributing plate comprises:
a plurality of gas-distributing openings through which the plasma passes; and
a frame defining the gas-distributing openings.

4. The substrate processing apparatus of claim 3, wherein the plurality of gas-distributing openings comprises:
an outer annular opening; and
an inner circular opening, and
wherein the frame comprises:
an outer ring-type frame surrounding the outer annular opening and defining an outline of the gas-distributing plate; and
an inner ring-type frame separating and defining the outer annular opening and the inner circular opening.

5. The substrate processing apparatus of claim 4, wherein a diameter of the inner circular opening is substantially the same as or greater than a diameter of the substrate.

6. The substrate processing apparatus of claim 4, wherein the frame further comprises:
an outer radial frame connecting the outer ring-type frame to the inner ring-type frame and dividing the outer annular opening into a plurality of outer arcuate openings; and
a plurality of inner linear frames dividing the inner circular opening into a plurality of inner polygonal openings.

7. The substrate processing apparatus of claim 6, wherein the plurality of the inner linear frames comprises:
at least one X-directional inner linear frame crossing the inner circular opening in an X-direction; and
at least one Y-directional inner linear frame crossing the inner circular opening in a Y-direction, wherein the at least one Y-directional inner linear frame is perpendicular to the X-directional inner linear frame.

8. The substrate processing apparatus of claim 7, wherein a geometric center of the inner ring-type frame does not match a geometric center of the plurality of the inner linear frames, wherein geometric shapes of the plurality of the inner linear frames are asymmetric in the inner circular opening.

9. The substrate processing apparatus of claim 4, wherein the frame comprises:
a plurality of inner concentric ring-type frames separating and defining the inner circular opening into a plurality of inner concentric annular openings; and
a plurality of inner radial frames separating and defining the plurality of the inner concentric annular openings into a plurality of inner arcuate openings,
wherein the plurality of the inner concentric ring-type frames and the plurality of the inner radial frames form a cobweb shape.

10. The substrate processing apparatus of claim 9, wherein the plurality of the inner radial frames are not linearly continuous from a geometric center of the cobweb shape to the inner ring-type frame, and
wherein each of the plurality of the inner concentric ring-type frames has a zigzag shape comprising two or more diameters along a circumference of the plurality of the inner concentric ring-type frames.

11. The substrate processing apparatus of claim 4, wherein the inner ring-type frame comprises a plurality of gas inlet holes.

12. The substrate processing apparatus of claim 1, wherein the rotating part comprises:
a hollow shaft through which a lower portion of the susceptor passes;
a housing surrounding an outer surface of the hollow shaft; and
a rotation driver connected to a lower portion of the hollow shaft.

13. The substrate processing apparatus of claim 12, wherein the housing comprises:
a magnetic member disposed in the housing;
a magnetic fluid disposed on an inner circumferential surface of the housing; and
a cooling part disposed on an outer circumferential surface of the housing.

14. The substrate processing apparatus of claim 1, further comprising:
a baffle disposed under the susceptor, wherein the baffle comprises a plurality of radial slits; and
a vacuum pump disposed under the baffle, wherein the vacuum pump is configured to evacuate the inside of the chamber.

15. A substrate processing apparatus, comprising:
a vacuum chamber;
a plasma generator disposed at an upper portion of the vacuum chamber, wherein the plasma generator includes a gas inlet tube;
a susceptor disposed in the vacuum chamber, wherein the susceptor supports the substrate;
a gas-distributing plate configured to transfer plasma generated in the plasma generator to the susceptor;
a baffle disposed under the susceptor, wherein the baffle includes a plurality of slits;
a pocket chamber disposed outside the vacuum chamber, wherein the pocket member includes a rotating part configured to rotate the susceptor; and
a vacuum pump disposed at a lower portion of the vacuum chamber, wherein the vacuum pump is configured to evacuate the vacuum chamber.

16.-20. (canceled)

21. A substrate processing apparatus, comprising:
a vacuum chamber;
a plasma generator disposed at an upper portion of the vacuum chamber;
a susceptor disposed at an intermediate portion of the vacuum chamber and supporting the substrate;
a gas-distributing plate disposed between the plasma generator and the susceptor; and
a pocket chamber disposed outside and under the vacuum chamber,
wherein the pocket chamber includes a rotating part configured to rotate the susceptor.

22. The substrate processing apparatus of claim 21, wherein the gas-distributing plate comprises:
gas-distributing openings including an outer annular opening and an inner circular opening through which the plasma passes; and
an outer ring-type frame defining an outline of the gas-distributing openings and an inner ring-type frame configured to separate and define the outer annular opening and the inner circular opening,
wherein the outer ring-type frame and the inner ring-type frame are concentric circles.

23. The substrate processing apparatus of claim 22, wherein the gas-distributing plate includes:
an X-directional inner linear frame and a Y-directional inner linear frame dividing the inner circular opening into a plurality of inner polygonal openings, and
a geometric center of the inner ring-type frame does not match a geometric center of the X-directional and Y-directional inner linear frames.

24. The substrate processing apparatus of claim 22, wherein the gas-distributing plate comprises:
inner radial frames dividing the inner circular opening into a plurality of inner concentric annular openings; and
inner concentric ring-type frames dividing the plurality of inner concentric annular openings into a plurality of inner arcuate openings,
wherein a geometric center of the inner ring-type frame does not match a geometric center of the inner concentric ring-type frames.

25. The substrate processing apparatus of claim 21, wherein the rotating part comprises:
a hollow shaft through which a lower portion of the susceptor passes;
a housing surrounding an outer surface of the hollow shaft; and
a rotation driver connected to a lower portion of the hollow shaft, and
wherein the housing comprises:
a magnetic member disposed thereinside;
a magnetic fluid disposed on an inner circumferential surface thereof; and
a cooling part disposed on an outer circumferential surface thereof.
